(19) United States
(12) Patent Application Publication
(10) Pub. No.: US 2012/0257135 A1
(43) Pub. Date: Oct. 11, 2012

(54) FAN-OUT DESIGN, METHOD OF FORMING FAN-OUT DESIGN, AND LCD ADOPTING THE FAN-OUT DESIGN

(75) Inventors: Chenghung Chen, Guangdong (CN); Zui Wang, Guangdon (CN)

(73) Assignee: SHENZHEN CHINA STAR OPTOELECTRONICS TECHNOLOGY CO. LTD., Shenzhen (CN)

(21) Appl. No.: 13/265,140

(22) PCT Filed: Apr. 19, 2011
(86) PCT No.: PCT/CN11/73019

§ 371 Date: Oct. 19, 2011

(30) Foreign Application Priority Data
Apr. 8, 2011 (CN) 201110087695.8

(51) Int. Cl. G02F 1/1333; H01L 21/768

(52) U.S. Cl. 349/56; 438/586; 257/E21.575

(57) ABSTRACT

The present invention proposes a fan-out design, a method of forming the fan-out design and a liquid crystal display adopting the fan-out design. The fan-out design has at least two metallic layers. The metallic layers, serving as conducting wires, are connected to different chip pins for transmitting signals. The two metallic layers are not overlapped near the chip pins and are overlapped away from the chip pins. The two metallic layers are separated from each other with an insulating layer. The two metallic layers are not overlapped near the chip pins, so the thickness of the chip pins is thinner. This can avoid the thickness of the fan-out design from being too thick. Besides, the two metallic layers are overlapped away from the chip pins, so the gap between every two conducting wires is greater. It makes the design and the manufacturing process easier and improves yield rate as well.

### BACKGROUND OF THE INVENTION

1. Field of the Invention

The present invention relates to a fan-out design used in a liquid crystal display (LCD), and more particularly, to a fan-out design where conducting wires in different positions have different structures.

2. Description of the Prior Art

An advanced monitor with multiple functions is an important feature for use in current consumer electronic products. Liquid crystal displays (LCDs) which are colorful monitors with high resolution are widely used in various electronic products such as monitors for mobile phones, personal digital assistants (PDAs), digital cameras, laptop computers, and notebook computers.

In an ordinary LCD structure, the LCD comprises a LCD panel and its related driver chips. Signals desired to be shown in the LCD panel are transmitted to the driver chips through a timing controller. Then, the signals are transmitted to each of the data lines on the LCD panel through the driver chips to drive the pixels on the LCD panel. Finally, images are shown on the LCD panel.

However, since each of the driver chips has hundreds of pins connected to the LCD panel, it is important for a circuit layout to find a way to pull wires to the LCD panel from the hundreds of pins properly. Therefore it is important to configure a fan-out design of each driver chip. In general, there are two problems about the fan-out design needing to be solved. The first problem is the gap between conducting wires. A small gap between the conducting wires increases the complexity of manufacturing because a precise alignment is needed in the manufacturing process. The second problem is the thickness of the pins. A conventional fan-out design is provided that multiple metallic layers are connected to a single pin at the same time to transmit the same signal, but such design increases a thickness of the chip pin.

Therefore, it requires the industry to provide a new fan-out design to solve problems related to the gap between conducting wires and the thickness of a chip pins.

### SUMMARY OF THE INVENTION

An object of the present invention is to provide a fan-out design. The fan-out design can solve problems related to the gap between conducting wires and the thickness of pins of a chip, and thereby can solve the problem occurring in the prior art.

According to the present invention, a fan-out design of a chip comprises: providing a chip having a first pin and a second pin, the plurality of first pins being different from the plurality of second pins, forming a first metallic layer and a second metallic layer, wherein the first metallic layer does not overlap the second metallic layer in a first region, while the first metallic layer and are the second metallic layer overlapped and are separated by an insulating layer in a second region. The first region links to the second region and the first metallic layer and the second metallic layer are connected to the first pin and the second pin in first region, respectively.

In one aspect of the present invention, the first metallic layer and the second metallic layer are connected to an active area of a substrate. The first metallic layer and the second metallic layer are connected to the active area of the substrate in a third region, and the first metallic layer does not overlap the second metallic layer in the third region. The third region connects to the second region. The substrate is a liquid crystal display panel, and the chip is a driver chip for driving the liquid crystal display panel.

In another aspect of the present invention, a first opening is formed over the first metallic layer and a second openings is formed over the second metallic layer corresponding to the first region. A transparent conducting layer covers on the first metallic layer through the first opening, so that the first pin is electrically connected to the first metallic layer. The transparent conducting layer covers on the second metallic layer through the second opening, so that the second pin is electrically connected to the second metallic layer.

According to the present invention, a liquid crystal display (LCD) comprising a plurality of driver chips, an active area, and a signal transmission region connected between the plurality of driver chips and the active area. Each of the driver chips comprises a plurality of first pins and a plurality of second pins. The plurality of first pins are alternately arranged with the plurality of second pins for outputting driving signals. The signal transmission region comprises a glass substrate, a first metallic layer, an insulating layer, and a second metallic layer. The glass substrate comprises a first region near the plurality of driver chips, a third region near the active area, and a second region between the first region and the third region. The first metallic layer disposed on the glass substrate and connected to the plurality of the first pins, is used for transmitting driving signals from the plurality of first pins to the active area. The insulating layer is disposed on the first metallic layer. The second metallic layer disposed on the insulating layer and connected to the plurality of second pins, is used for transmitting driving signals from the plurality of second pins to the active area. An area of the first region where the first metallic layer is projected and an area where the second metallic layer on the first region is projected are not overlapped, an area where the first metallic layer on the second region is projected and an area where the second metallic layer is projected on the second region are overlapped, and an area where the first metallic layer is projected on the third region and an area where the second metallic layer is projected on the third region are not overlapped.

According to the present invention, a method of forming a fan-out design of a chip, comprising: providing a chip comprising a first pin and a second pin, the first pin being different from the second pin; providing a glass substrate and an active area, the glass substrate comprising a first region near the chip, a third region near the active area, and a second region between the first region and the third region, the active area formed on the glass substrate; forming a first metallic layer on the glass substrate; forming a gate insulating layer on the first metallic layer and on the glass substrate; etching the gate insulating layer for forming a plurality of first openings over the first metallic layer of the first region and over the first metallic layer of the third region, respectively; forming a second metallic layer on the gate insulating layer, an area where the first metallic layer is projected on the first region is not overlapped with an area where the second metallic layer is projected on the first region, an area where the first metallic layer is projected on the second region is overlapped with an area where the second metallic layer on the second region is projected, and an area where the first metallic layer is projected on the third region is not overlapped with an area where the second metallic layer is projected on the third region; forming a passivation layer on the second metallic layer and on the gate insulating layer; etching the passivation layer for forming a plurality of second openings over the second metallic layer of the first region and over the second metallic layer of the third region, respectively; and forming a transparent conducting layer on the plurality of first openings and on the plurality of second openings, so that the first metallic layer is connected to the first pin and the active area through the transparent conducting layer and the second metallic layer is connected to the second pin and the active area through the transparent conducting layer.

In one aspect of the present invention, the active area comprises a plurality of transistors. The first metallic layer is connected to the first pin and the plurality of transistors through the transparent conducting layer. The second metallic layer is connected to the second pin and the plurality of transistors through the transparent conducting layer.

Contrast to the prior art, the fan-out design of the present invention comprises two different metallic layers serving as the conducting wires connected to the chip pins and to the active area of the substrate. The two metallic layers are disposed alternately near the chip pins and the active area while are overlapped in the other areas. It can be seen that the thickness of the area near the chip pins and the active area is avoided from being big because the two metallic layers are not overlapped near the chip pins and the active area and that the gap between the conducting wires is avoided from being small because the two metallic layers are overlapped in the other areas. In this way, not only the manufacturing process of the fan-out design is simplified but also yield rate is improved.

These and other features, aspects and advantages of the present disclosure will become understood with reference to the following description, appended claims and accompanying figures.

### BRIEF DESCRIPTION OF THE DRAWINGS

FIG. 1 is a function block diagram showing an LCD according to an embodiment of the present invention.

FIG. 2 is a schematic diagram showing a fan-out design in the signal transmission region.

FIG. 3 is a cross-sectional view of a line segment D-D′ in the signal transmission region shown in FIG. 2.

FIG. 4 is a cross-sectional view of a line segment F-F′ in the second region in the signal transmission region shown in FIG. 2.

### DETAILED DESCRIPTION OF THE PREFERRED EMBODIMENTS

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures.

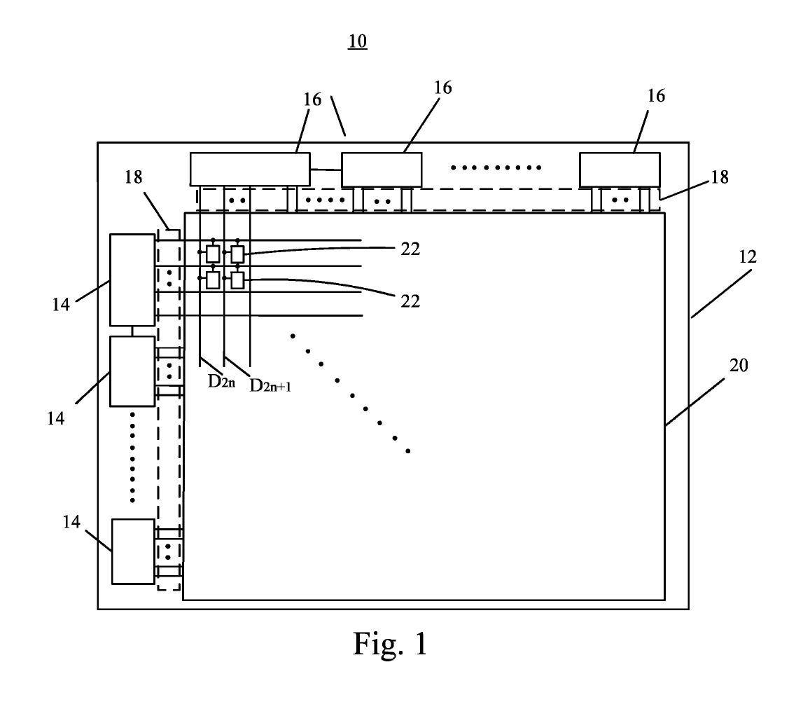

Referring to FIG. 1, FIG. 1 is a function block diagram showing an LCD 10 according to an embodiment of the present invention. The LCD 10 comprises an active area 20, a plurality of gate driver chips 14, a plurality of source driver chips 16, and signal transmission regions 18. In this embodiment, the LCD 10 adopts the chip on glass (COG) technology; that is, the plurality of gate driver chips 14 and the plurality of source driver chips 16 adhere to a glass substrate 12 directly. The plurality of gate driver chips 14 and the plurality of source driver chips 16 transmit signals to the active area 20 through the signal transmission regions 18. The active area 20 is laid out on the glass substrate 12. A plurality of transistors 22 are disposed on the active area 20. Each pixel unit corresponds to a pixel electrode (not shown) and a transistor 22. When the gate driver chip 14 outputs a scanning signal to turn on the plurality of transistors 22 in the pixel units of the first row, the source driver chips 16 output corresponding data signals to the pixel electrodes corresponding to the pixel units of the first row through data lines D₂ₙ and D₂ₙ₊₁, so that the pixel electrodes can be charged up to desired voltage to show different gray levels. Afterwards, the gate driver chip 14 outputs scanning signal to turn on the plurality of transistors 22 in the pixel units of the second row, and then the source driver chip 16 charges pixel electrodes in the second row through the plurality of transistors 22 in the second row. Following this charging order, all of the pixel electrodes in the active area 20 can be fully charged. Once again, the plurality of transistors 22 in the pixel units of the first row start to be scanned.

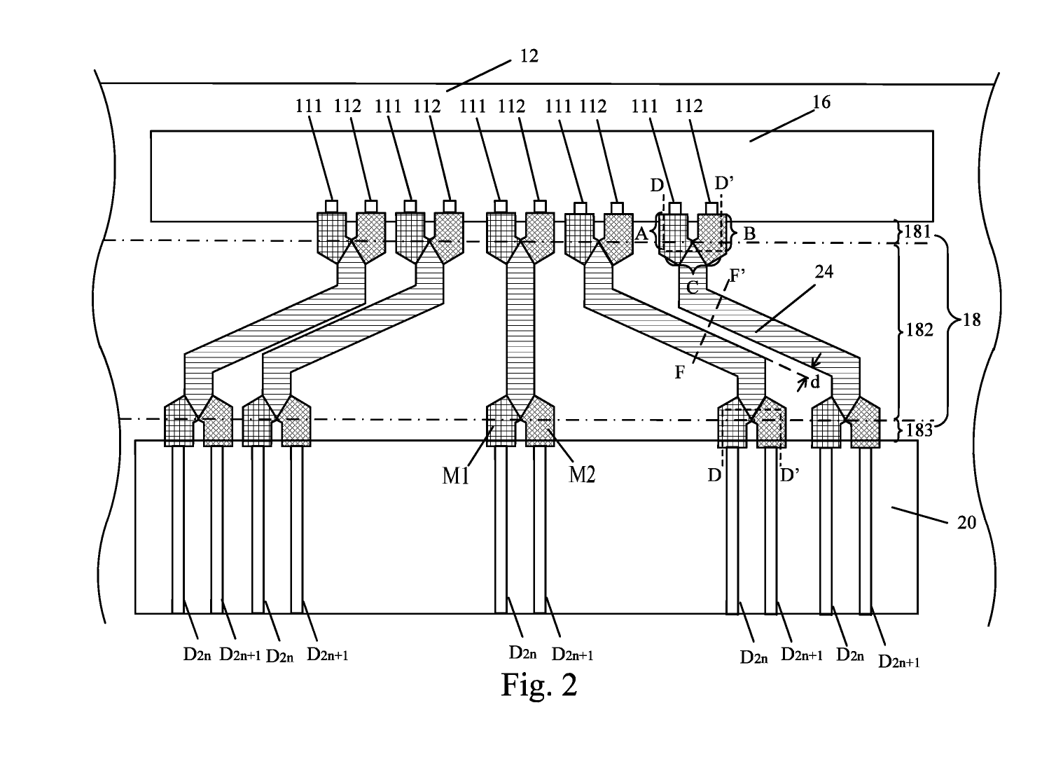

Referring to FIG. 2, FIG. 2 is a schematic diagram showing a fan-out design in the signal transmission region 18. The source driver chip 16 is used for elaborations in this embodiment. In practical applications, any chips which are disposed on the glass substrate 12 and comprise a plurality of pins, such as the gate driver chip 14, can be applied to a structure designed according to the present invention as well.

As FIG. 2 shows, the source driver chip 16 comprises a plurality of first pins 111 and a plurality of second pins 112. Two metallic layers M1 and M2 used as conducting wires are disposed on the signal transmission region 18. The metallic layers M1 and M2 are connected to the plurality of first pins 111 and the plurality of second pins 112 of the source driver chip 16 respectively and transmit the data signal from the source driver chip 16 to the plurality of transistors (not shown) on the active area 20 through the data lines D₂ₙ and D₂ₙ₊₁. It is notified that the disposition of the metallic layers M1 and M2 near the chip pins is different from that of the metallic layers M1 and M2 in the other areas. For example, the metallic layer M1 is disposed alternately with the metallic layer M2 in a first region 181 which is near the first pins 111 and the second pins 112 of the source driver chip 16. Each of the metallic layers M1 is connected to each of the first pins 111, and each of the metallic layers M2 is connected to each of the second pins 112. A conducting wire 24 in the second region 182 represents an overlapping area for both of the metallic layer M1 and the metallic layer M2 that are projected onto the second region 182. The metallic layer M1 and the metallic layer M2 do not touch directly. The metallic layer M1 and the metallic layer M2 are disposed alternately in the third region 183 near the active area 20. Each of the metallic layers M1 is connected to the drain (not shown) of the transistors of the active area 20 through the data lines D₂ₙ₊₁, while each of the metallic layers M2 is connected to the drain of the transistors of the active area 20 through the data lines D₂ₙ.

The metallic layer forms, e.g. five conducting wires, connected to the plurality of pins 111 of the source driver chip 16. The metallic layer M2 forms, e.g. five conducting wires, connected to the plurality of pins 112 of the source driver chip 16. However, it is to be understood that, FIG. 2 where the source driver chip 16, the metallic layer M1, and the metallic layer M2 are illustrated is simplified to facilitate the description of the present invention. In other words, the number of the pins and the number of the conducting wires formed by the metallic layers M1/M2 illustrated in FIG. 2 are an exemplary embodiment of the present invention. This exemplary embodiment is not to be interpreted as limiting. In practical applications, the source driver chip 16 comprises more pins than those shown in FIG. 2, and the metallic layers M1/M2 also comprise more conducting wires than those shown in FIG. 2. Such changes and modifications also fall within the scope of the present invention.

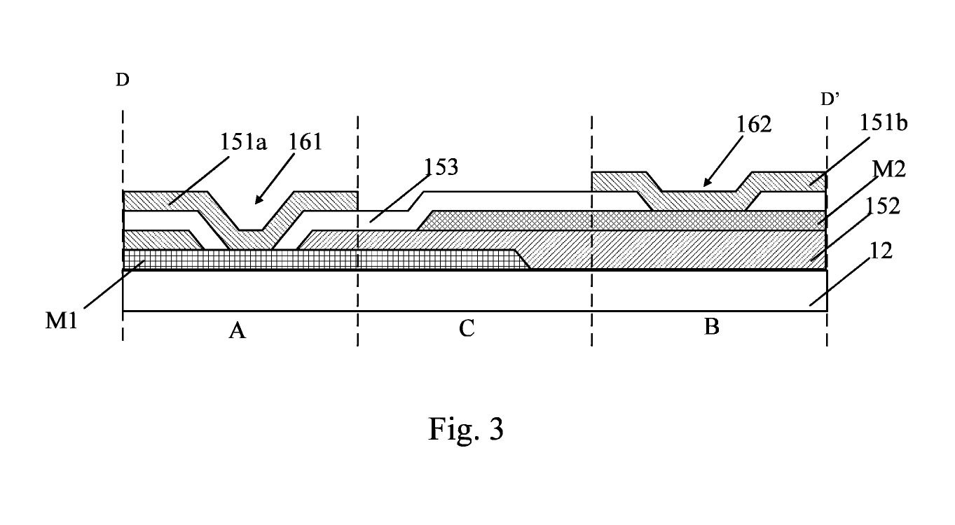

Referring to FIG. 3, FIG. 3 is a cross-sectional view of a line segment D-D′ in the signal transmission region 18 shown in FIG. 2. The first region 181 corresponding to the glass substrate 12 represents area A and area B in FIG. 3. Only the metallic layer M1 is disposed on the Area A, and only the metallic layer M2 is disposed on the area B. It is clear that the metallic layer M1 and the metallic layer M2 are not overlapped (are disposed alternately). In other words, the area where the metallic layer M1 is projected on the first region 181 is not overlapped with the area where the metallic layer M2 is projected on the first region 181. The driving signal output by the first pin 111 and the second pin 112 of the source driver chip 16 is transmitted to the metallic layers M1 and M2 through the transparent conducting layers 151a and 151b, respectively. The transparent conducting layers 151a and 151b are not electrically connected to each other. The transparent conducting layers 151a and 151b are made of indium tin oxide (ITO). In addition, to prevent the metallic layer M1 from being electrically connected to the metallic layer M2, a gate insulting layer 152 is formed between the metallic layer M1 and the metallic layer M2 according to the embodiment. The gate insulting layer 152 is a low-k dielectric layer made of SiOₓN_{y}, SiNₓ or the like.

In addition, the disposition of the metallic layer M1 and the metallic layer M2 in the third region 183 near the active area 20 of the LCD resembles that in the first region 181. As FIG. 3 shows, the metallic layer M1 and the metallic layer M2 in the third region 183 are disposed alternately; that is, the area where the metallic layer M1 is projected on the third region 183 is not overlapped with the area where the metallic layer M2 is projected on the third region 183. The metallic layer M1 and the metallic layer M2 are connected to the data lines D₂ₙ and D₂ₙ₊₁ in the active area 20 through the transparent conducting layers 151a and 151b, respectively. Afterwards, the metallic layer M1 and the metallic layer M2 are connected to their corresponding transistors 22 (referring to FIG. 2) through the data lines D₂ₙ and D₂ₙ₊₁. The disposition of the metallic layer M1 and the metallic layer M2 in the third region 183 is similar to that in the first region 181. To simplify the description, no more details and illustrations are to be presented hereinafter.

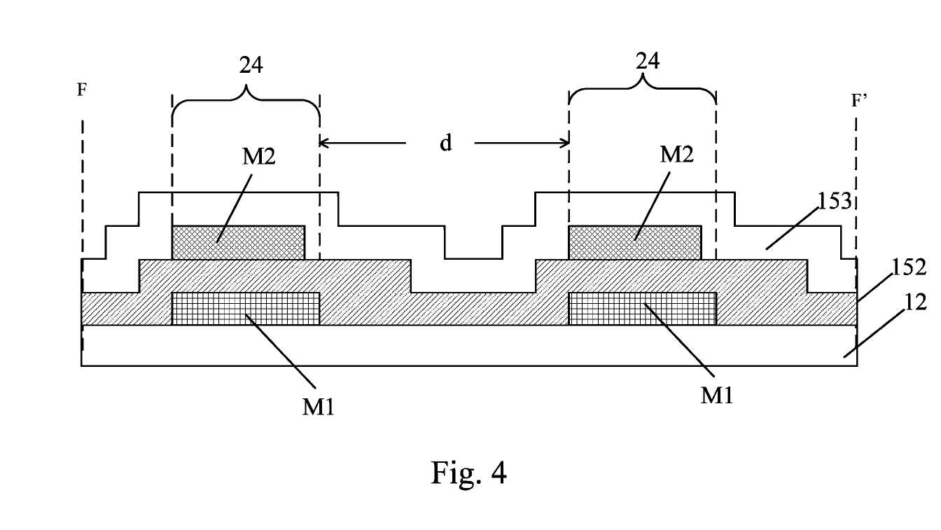

Referring to FIG. 2 and FIG. 4, FIG. 4 is a cross-sectional view of a line segment F-F′ in the second region 182 in the signal transmission region 18 shown in FIG. 2. The disposition of the metallic layer M1 and the metallic layer M2 in the second region 182 is different from that of the metallic layer M1 and the metallic layer M2 in the first region 181 and in the third region 183. The metallic layer M1 and the metallic layer M2 are overlapped but not connected, forming a conducting wire 24. Every two neighboring conducting wires 24 are separated from one another by a gap d. As FIG. 4 shows, the metallic layer M1 and the metallic layer M2 are overlapped and separated by the gate insulating layer 152; that is, the area where the metallic layer M1 is projected on the second region 182 is overlapped with the area where the metallic layer M2 is projected on the second region 182. It is notified that the metallic layer M1 and the metallic layer M2 are disposed alternately in the first region 181 and in the third region 183, so the thickness of the metallic layer M1 or the metallic layer M2 in the area 181 and the third region 183 is smaller than that of the overlapping area of the metallic layer M1 and the metallic layer M2 in the second region 182. Thus, the problem that the thickness of the chip pins is big occurring in the prior art can be solved. Moreover, the metallic layer M1 and the metallic layer M2 are overlapped in the second region 182, so the gap d between every two conducting wires is small. The gap d formed under condition that the metallic layer M1 and the metallic layer M2 are overlapped in the second region 182 is bigger than under condition that the metallic layer M1 and the metallic layer M2 are alternative disposed in the first region 181. In this way, the restriction in the manufacturing process for the second region 182 is looser and relatively simpler. In addition, a passivation layer 153 is formed on the metallic layer M2 to prevent the alignment of the LC molecules on the metallic layers M1 and M2 from being affected by the electric potential of the metallic layers M1 and M2 directly.

Please refer to FIGS. 2 through 4. One embodiment of the present invention is introduced to form the manufacturing process of the above-mentioned structure. Firstly, the metallic thin film (not shown) is deposited on the glass substrate 12, and the metallic thin film is etched to form the metallic layer M1 connected to the pin 111 of the chip. Next, the gate insulating layer 152 made from SiOxNy or SiNx is formed by undergoing chemical vapor deposition (CVD) on the metallic layer M1 and the glass substrate 12. Next, the gate insulating layer 152 is etched to form a first opening 161 (referring to FIG. 3) on the metallic layer M1 corresponding to the gate insulating layer 152. Next, the metallic thin film (not shown) is deposited on the gate insulating layer 152, and the metallic thin film is etched to form the metallic layer M2 connected to the pin 112 of the chip. Next, the passivation layer 153 is deposited on the metallic layer M1, the gate insulating layer 152, and the metallic layer M2. Then, the passivation layer 153 is etched to form a second opening 162 on the metallic layer M2 corresponding to the passivation layer 153. Next, the transparent conducting thin film (not shown) is deposited on the metallic layer M1, the metallic layers M2, and the passivation layer 153, and then the transparent conducting thin film is etched to form the transparent conducting layers 151a and 151b corresponding to the first opening 161 and the second opening 162, respectively. Thus, the metallic layer M1 is electrically connected to the transparent conducting layer 151a at the first opening 161 in the first region 181 and in the third region 183, so that electric signals can be transmitted from the pin 111 to the data line D₂ₙ through the metallic layer M1 and then can be transmitted to the plurality of transistors 22 of the active area 20. The metallic layer M2 is electrically connected to the transparent conducting layer 151b at the second opening 162 in the first region 181 and in the third region 183, so that electric signals can be transmitted from the pin 112 to the data line D₂ₙ₊₁ through the metallic layer M2 and then can be transmitted to the plurality of transistors 22 of the active area 20.

It is notified that the above-mentioned manufacturing process is one of the embodiments of the present invention, but not to limit the present invention. In practical applications, the fan-out design of the present invention is not limited to the above-mentioned manufacturing method.

It is also notified that, to facilitate illustrations and descriptions of the concepts of the present invention, the source driver chip 16 is exemplified in the aforementioned embodiment. Actually, this embodiment is a preferred embodiment of the present invention, instead of being meant to limit the present invention. In practical applications, the source driver chip 16 can be replaced by any chips, and the active area of the LCD panel can be the active area of other kind of substrate. Such a corresponding replacement still belongs to the scope of the present invention.

While the present invention has been described in connection with what is considered the most practical and preferred embodiments, it is understood that this invention is not limited to the disclosed embodiments but is intended to cover various arrangements made without departing from the scope of the broadest interpretation of the appended claims.

What is claimed is:

1. A liquid crystal display (LCD), comprising a plurality of driver chips and an active area, each of the driver chips comprising a plurality of first pins and a plurality of second pins, the plurality of first pins being alternately arranged with the plurality of second pins for outputting driving signals, characterized in that: the LCD further comprises a signal transmission region connected between the plurality of driver chips and the active area, comprising:
a glass substrate, comprising a first region near the plurality of driver chips, a third region near the active area, and a second region between the first region and the third region;
a first metallic layer, disposed on the glass substrate and connected to the plurality of the first pins, for transmitting driving signals from the plurality of first pins to the active area;
an insulating layer, disposed on the first metallic layer; and
a second metallic layer, disposed on the insulating layer and connected to the plurality of second pins, for transmitting driving signals from the plurality of second pins to the active area,
wherein an area where the first metallic layer is projected on the first region and an area where the second metallic layer is projected on the first region are not overlapped, an area where the first metallic layer is projected on the second region and an area where the second metallic layer is projected on the second region are overlapped, and an area where the first metallic layer is projected on the third region and an area where the second metallic layer is projected on the third region are not overlapped.

2. The LCD as claimed in claim 1, characterized in that: a plurality of first openings are formed over the first metallic layer and a plurality of second openings are formed over the second metallic layer on the first region corresponding to the glass substrate.

3. The LCD as claimed in claim 2, characterized in that: the signal transmission region further comprises a transparent conducting layer which covers on the first metallic layer through the plurality of first openings, so that the plurality of first pins are electrically connected to the first metallic layer.

4. The LCD as claimed in claim 3, characterized in that: the transparent conducting layer covers on the second metallic layer through the plurality of second openings, so that the plurality of second pins are electrically connected to the second metallic layer.

5. The LCD as claimed in claim 3, characterized in that: the transparent conducting layer is made of indium tin oxide (ITO).

6. The LCD as claimed in claim 1, characterized in that: the gate insulting layer is made of SiOₓ N_{y} or SiN_{X}.

7. A fan-out design of a chip comprising: providing a chip having a first pin and a second pin, the plurality of first pins being different from the plurality of second pins, characterized in that: forming a first metallic layer and a second metallic layer, wherein the first metallic layer does not overlap the second metallic layer in a first region, while the first metallic layer and are the second metallic layer overlapped and are separated by an insulating layer in a second region; wherein the first region links to the second region and the first metallic layer and the second metallic layer are connected to the first pin and the second pin in first region, respectively.

8. The fan-out design of a chip as claimed in claim 7, characterized in that: the first metallic layer and the second metallic layer are connected to an active area of a substrate.

9. The fan-out design of a chip as claimed in claim 8, characterized in that: the first metallic layer and the second metallic layer are connected to the active area of the substrate in a third region, and the first metallic layer does not overlap the second metallic layer in the third region.

10. The fan-out design of a chip as claimed in claim 9, characterized in that: the third region connects to the second region.

11. The fan-out design of a chip as claimed in claim 10, characterized in that: the substrate is a liquid crystal display panel, and the chip is a driver chip for driving the liquid crystal display panel.

12. The fan-out design of a chip as claimed in claim 7, characterized in that: a first opening is formed over the first metallic layer and a second openings is formed over the second metallic layer corresponding to the first region.

13. The fan-out design of a chip as claimed in claim 12, characterized in that: a transparent conducting layer covers on the first metallic layer through the first opening, so that the first pin is electrically connected to the first metallic layer.

14. The fan-out design of a chip as claimed in claim 13, characterized in that: the transparent conducting layer covers on the second metallic layer through the second opening, so that the second pin is electrically connected to the second metallic layer.

15. The fan-out design of a chip as claimed in claim 13, characterized in that: the transparent conducting layer is made of indium tin oxide (ITO).

16. The fan-out design of a chip as claimed in claim 7, characterized in that: the gate insulting layer is made of SiOₓN_{y} or SiN_{X}.

17. A method of forming a fan-out design of a chip, comprising: providing a chip comprising a first pin and a second pin, the first pin being different from the second pin; providing a glass substrate and an active area, the glass substrate comprising a first region near the chip, a third region near the active area, and a second region between the first region and the third region, the active area formed on the glass substrate, in characterized in that the method further comprises:
forming a first metallic layer on the glass substrate;
forming a gate insulating layer on the first metallic layer and on the glass substrate;
etching the gate insulating layer for forming a plurality of first openings over the first metallic layer of the first region and over the first metallic layer of the third region, respectively;
forming a second metallic layer on the gate insulating layer, an area where the first metallic layer is projected on the first region is not overlapped with an area where the second metallic layer is projected on the first region, an area where the first metallic layer is projected on the second region is overlapped with an area where the second metallic layer is projected on the second region, and an area of the third region where the first metallic layer is projected is not overlapped with an area where the second metallic layer is projected on the third region;
forming a passivation layer on the second metallic layer and on the gate insulating layer;
etching the passivation layer for forming a plurality of second openings over the second metallic layer of the first region and over the second metallic layer of the third region, respectively; and
forming a transparent conducting layer on the plurality of first openings and on the plurality of second openings, so that the first metallic layer is connected to the first pin and the active area through the transparent conducting layer and the second metallic layer is connected to the second pin and the active area through the transparent conducting layer.

18. The method of forming the fan-out design as claimed in claim 17, characterized in that: the active area comprises a plurality of transistors, the first metallic layer is connected to the first pin and the plurality of transistors through the transparent conducting layer.

19. The method of forming the fan-out design as claimed in claim 18, characterized in that: the second metallic layer is connected to the second pin and the plurality of transistors through the transparent conducting layer.

20. The method of forming the fan-out design as claimed in claim 17, characterized in that: the transparent conducting layer is made of indium tin oxide (ITO).
